(19) United States
(12) Patent Application Publication
(10) Pub. No.: US 2026/0136600 A1
(43) Pub. Date: May 14, 2026

(54) SEMICONDUCTOR DEVICE AND METHOD OF FORMING THE SAME

(71) Applicant: Taiwan Semiconductor Manufacturing Company, Ltd., Hsinchu (TW)

(72) Inventors: Hsin-Huang Lin, Taichung City (TW); Ta-Chun LIN, Hsinchu (TW); Jhon Jhy Liaw, Hsinchu County (TW)

(73) Assignee: Taiwan Semiconductor Manufacturing Company, Ltd., Hsinchu (TW)

(21) Appl. No.: 18/945,563

(22) Filed: Nov. 13, 2024

(51) Int. Cl. H01L 29/423; H01L 21/8234; H01L 27/088; H01L 29/06; H01L 29/08; H01L 29/66; H01L 29/775; H01L 29/786

(52) U.S. Cl. CPC H10D 30/6735; H10D 30/014; H10D 30/43; H10D 30/6757; H10D 62/121; H10D 62/151; H10D 64/017; H10D 84/0128; H10D 84/013; H10D 84/0135; H10D 84/0144; H10D 84/038; H10D 84/83

(57) ABSTRACT

A semiconductor device and a method of forming the same are provided. The semiconductor device includes a substrate, semiconductor channel layers, source/drain structures, an insulation layer and a frontside source/drain contact. The semiconductor channel layers are stacked over the substrate and spaced apart from each other. The source/drain structures are disposed over the substrate. The semiconductor channel layers are located between the adjacent source/drain structures. The insulation layer is disposed between the source/drain structures and a frontside of the substrate. The frontside source/drain contact extends into one of the source/drain structures. A bottom end of the frontside source/drain contact is located between a top surface of a bottommost semiconductor channel layers of the bottommost semiconductor channel layers and the frontside of the substrate.

### BACKGROUND

In the manufacturing processes of integrated circuits, electronic circuits with components such as transistors are formed from semiconductor-based wafers. Continuously scaling down and high integration density of semiconductor devices have increased the complexity of semiconductor manufacturing processes.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 20 are schematic cross-sectional views illustrating a portion of a semiconductor device at various stages of a method for forming the semiconductor device according to some embodiments of the present disclosure.

FIG. 21 through FIG. 22 are schematic cross-sectional views illustrating a portion of a semiconductor device at various stages of a method for forming the semiconductor device according to some embodiments of the present disclosure.

FIG. 23 through FIG. 25 are schematic cross-sectional views illustrating a portion of a semiconductor device at various stages of a method for forming the semiconductor device according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

According to embodiments of the present disclosure, a semiconductor device is described. The semiconductor device includes a substrate, semiconductor nanosheets, source/drain structures and frontside source/drain contacts. The frontside source/drain contacts extend through the source/drain structures and a bottom of the frontside source/drain contacts is at a level between a top surface of the bottommost semiconductor nanosheets and a frontside of the substrate, so that the contact resistance between the frontside source/drain contacts and the source/drain structures can be reduced as well as the current spreading between the frontside source/drain contacts and the semiconductor nanosheets is improved, and thereby the electrical performance of the semiconductor device 10 can be improved.

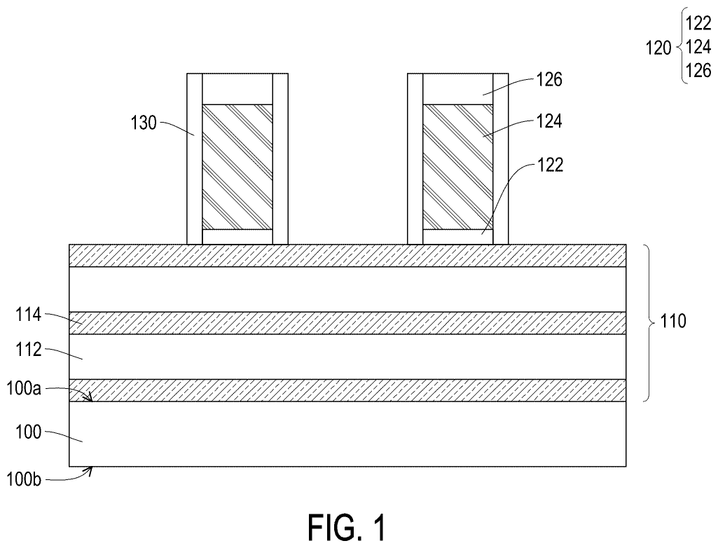

FIG. 1 through FIG. 20 are schematic cross-sectional views illustrating a portion of a semiconductor device 10 at various stages of a method for forming the semiconductor device 10 according to some embodiments of the present disclosure.

Referring to FIG. 1, a substrate 100 and a fin stack 110 stacked over the substrate are provided. The substrate 100 is placed with its frontside 100a facing up and its backside 100b facing down in FIG. 1. From FIG. 1 to FIG. 20, only a portion of the device region of the semiconductor device 10 is shown for illustration purposes. It is understood that only one fin stack 110 is shown in FIG. 1, but there may be multiple parallel arranged fin stacks 110 formed over the substrate 100.

In some embodiments, the substrate 100 includes a semiconductor substrate. In one embodiment, the substrate 100 comprises a bulk semiconductor substrate such as a crystalline silicon substrate, and may be doped (e.g., p-type or n-type semiconductor substrate) or undoped. In one embodiment, the substrate 100 comprises a silicon-on-insulator substrate or a germanium-on-insulator substrate. In some embodiments, the substrate 100 includes a semiconductor substrate made of other suitable elemental semiconductor, such as diamond or germanium; a suitable compound semiconductor, such as gallium arsenide (GaAs), silicon carbide (SiC), indium arsenide (InAs), or indium phosphide (InP); or a suitable alloy semiconductor, such as silicon-germanium (SiGe), gallium arsenic phosphide (GaAsP), or gallium indium phosphide (GaInP).

In some embodiments, the fin stack 110 includes first semiconductor layers 112 and second semiconductor layers stacked alternatively over the frontside 100a of the substrate 100. In some embodiments, the first semiconductor layers 112 are formed of a first semiconductor material, the second semiconductor layers 114 are formed of a second semiconductor material, and the second semiconductor material is different from the first semiconductor material. For example, the first or second semiconductor material may include one or more selected from silicon, germanium, SiC, SiGe, GaAs, InSb, GaP, GaSb, InAlAs, InGaAs, GaSbP, GaAsSb or InP. In some embodiments, the first semiconductor layers 112 may include silicon, silicon carbide, or the like, and the second semiconductor layers 114 may include silicon germanium (SiGe) or the like. In some embodiments, the first semiconductor layers 112 are of the same semiconductor material as the substrate 100.

In some embodiments, the fin stack 110 may be formed by performing alternating epitaxial growth processes to form second semiconductor material layers (not shown) and first semiconductor material layers (not shown) in alternation, and then patterning the first semiconductor material layers, the second semiconductor material layers and the substrate 100 to form the fin stack 110.

In some embodiments, the formation of the first semiconductor material layers or the second semiconductor material layers include one or more processes selected from chemical vapor deposition (CVD), atomic layer deposition (ALD), vapor phase epitaxy (VPE), molecular beam epitaxy (MBE), or the like. In some embodiments, the patterning may include one or more suitable etching processes, such as reactive ion etch (RIE), neutral beam etch (NBE), or a combination thereof. In some embodiments, isolation structures (not shown) may be included in the substrate 100 for isolation.

FIG. 1 schematically shows several semiconductor layers for the fin stack 110, but it is not limited thereto. It is understood that the number of the semiconductor layers of the fin stack 110 is not limited and may be adjusted based on practical requirements.

Referring to FIG. 1, dummy structures 120 are formed on the fin stacks 110, where each dummy structure 120 includes a dummy dielectric layer 122, a dummy gate layer 124 and a hard mask layer 126. In some embodiments, the dummy structures 120 are formed over and across over multiple parallel fin stacks 110, as the extending direction of the dummy structures 120 is intersected with the extending direction of the fin stacks 110. In FIG. 1, there are two dummy structures 120 shown schematically, but it is not limited. It is understood that the number of the dummy structures 120 is not limited and may be adjusted based on practical requirements.

In some embodiments, the dummy structures 120 are formed by the following steps. First, a dummy dielectric material layer (not shown) for forming the dummy dielectric layer 122, a dummy gate material layer (not shown) for forming the dummy gate layer 124 and a hard mask material layer (not shown) for forming the hard mask layer 126 are sequentially deposited over the substrate and the fin stack 110. The deposition method of the dummy dielectric material layer, the dummy gate material layer and the hard mask material layer may include low-pressure CVD (LPCVD), CVD, plasma-enhanced CVD (PECVD), physical vapor deposition (PVD), ALD, thermal oxidation, e-beam evaporation, or other suitable deposition techniques, or combinations thereof. In some embodiments, the dummy dielectric material layer may include silicon oxide, the dummy gate material layer may include polysilicon, and the hard mask material layer may be a multi-layer that includes silicon oxide and silicon nitride. Then, using photolithography and etching processes, the hard mask material layer is patterned to form the hard mask layers 126 of the dummy structures 120. The photolithography process may include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. The etching process may include dry etching (e.g., RIE etching), wet etching, and/or other etching methods. Thereafter, using the hard mask layer 126 as the etch mask, the dummy dielectric material layer and the dummy dielectric material layer are patterned to form the dummy gate layers 124 and the dummy dielectric layers 122 of the dummy structures 120.

Referring to FIG. 1, sidewall spacers 130 are formed on sidewalls of the dummy structures 120. For example, a spacer layer (not shown) is deposited over the dummy structures 120 and the fin stack 110 by using CVD, subatmospheric CVD (SACVD), ALD or other suitable deposition methods, and then etched to form the sidewall spacers 130. In some embodiments the spacer layer includes one or more dielectric layers, and the one or more dielectric layers may include silicon oxide, silicon nitride, silicon carbide, silicon oxynitride, silicon carbonitride, silicon oxycarbide, silicon oxycarbonitride, and/or combinations thereof.

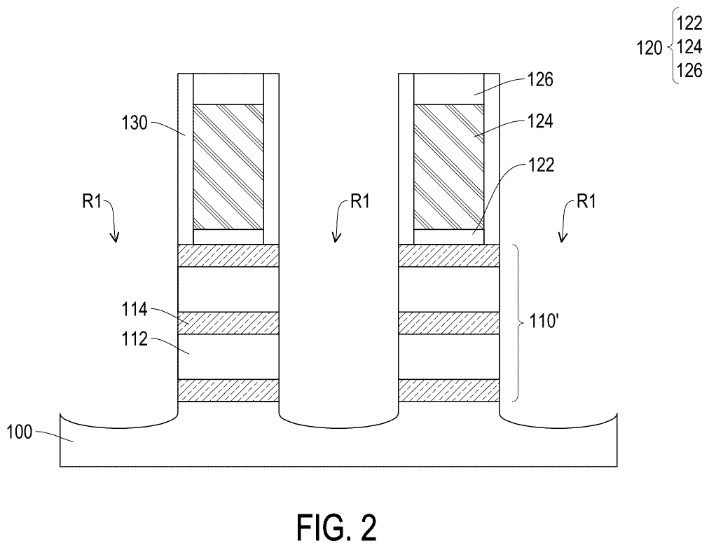

Referring to FIG. 2, the fin stack 110 is patterned to form recesses R1 in the fin stack 110. For example, using the dummy structures 120 and the sidewall spacers 130 as the masks, the fin stack 110 is etched and the substrate 100 may be further etched to form the recesses R1. The recesses R1 expose a portion of the substrate 100. In some embodiments, the etching process includes one or more anisotropic etching processes. As the materials of the first semiconductor layers 112 and the second semiconductor layers 114 of the fin stack 110 are different, the etching processes may include a series of etching processes using different etching recipes to have etch selectivity toward the predetermined materials.

During the etching process, the fin stack 110 which is covered by the dummy structure 120 is remained and the remained fin stack 110 are called stacks 110′ hereinafter. The stacks 110′ are in between adjacent recesses R1, and the opposite ends of the first semiconductor layers 112 and the opposite ends of the second semiconductor layers 114 of the stacks 110′ are exposed in the recesses R1. In some embodiments, the bottom of the recesses R1 is lower than the bottom surface of the bottommost layer of the second semiconductor 114 of the stack 110′. The recesses R1 define source/drain region of the device. Here, the source/drain region may refer to a source region or a drain region, individually or collectively dependent upon the context. Besides, the terms “top” and “bottom” hereinafter are relative to the substrate 100. For example, the top surface or the topmost layer is a surface or layer located furthest from the substrate 100, whereas the bottom surface or the bottommost layer is a surface or layer located closest to the substrate 100.

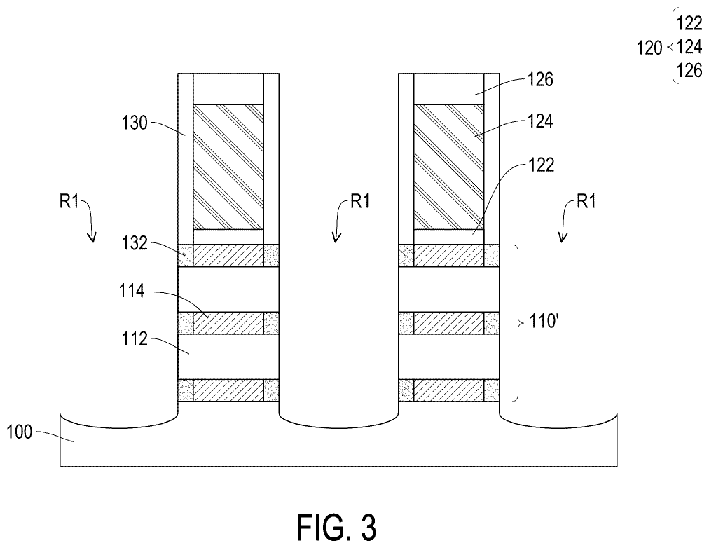

Referring to FIG. 3, inner spacers 132 are formed on sidewalls of the second semiconductor layers 114. For example, the second semiconductor layers 114 of the stacks 110′ are selectively and partially recessed to form side recesses (not shown) by performing a selective isotropic etching process through the recesses R1. Then, an inner spacer material such as silicon nitride is filled into the side recesses by an ALD process, a CVD process, or other suitable processes and then the inner spacer material is etched back to remove the extra inner spacer material by utilizing the sidewall spacers 130 as masks, thereby the inner spacers 132 are formed.

In some embodiments, the selective isotropic etching process may include a selective wet etching process or a selective dry etching process, which selectively etches the second semiconductor layers 114 with respect to the first semiconductor layers 112. In some embodiments, the second semiconductor layers 114 are sacrificial layers that will later be removed, and the first semiconductor layers 112 of the stacks 110′ are to form channel regions of the transistors.

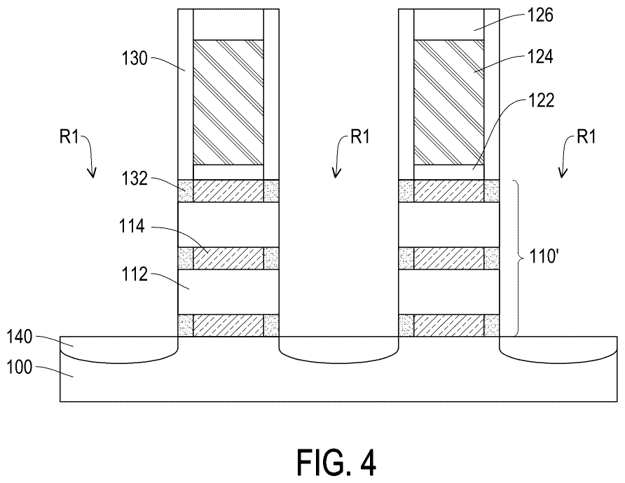

Referring to FIG. 4, a leakage block layer 140 is formed in recesses of the substrate 100 within the recesses R1. The leakage block layer 140 is configured to reduce current leakage into the substrate 100. In some embodiments, the leakage block layer 140 may be deposited using vapor-phase epitaxy (VPE), ultra-high vacuum chemical vapor deposition (UHV-CVD), molecular beam epitaxy (MBE), and/or other suitable epitaxy deposition processes. In some embodiments, the leakage block layer 140 include undoped semiconductor material, such as undoped silicon (Si), undoped silicon germanium (SiGe), or undoped germanium (Ge).

In some embodiments, the top surface of the leakage block layer 140 is about at the same level of the bottom surface of the bottommost layer of the second semiconductors 114 of the stacks 110′. That is, the top surface of the leakage block layer 140 and the bottom surface of the bottommost layer of the second semiconductors 114 of the stacks 110′ are substantially on the same horizontal plane.

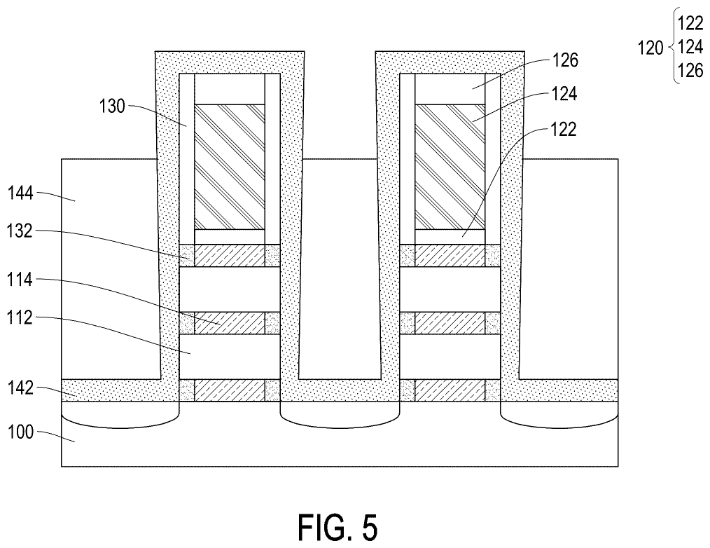

Referring to FIG. 5, an insulation material layer 142 is formed on the leakage block layer 140, the stacks 110′ (labeled in FIG. 4) and the dummy structures 120. For example, the insulation material layer 142 is conformally deposited over the substrate 100 by CVD, ALD, or other suitable processes. In some embodiments, the insulation material layer 142 formed on the top of the dummy structures 120 is thicker than the insulation material layer 142 formed on the leakage block layer 140. In some embodiments, the material of the insulation material layer 142 includes SiN, SiOC, SiCN, SiOCN, or the like.

Referring to FIG. 5, a dielectric layer 144 is formed on the insulation material layer 142 and in the recesses R1. For example, the bottom anti-reflective material layer (not shown) is deposited over the insulation material layer 142 by CVD, spin-coating or other suitable methods and then etched back to form the dielectric layer 144. In some embodiments, the dielectric layer 144 may comprise SiON, a polymer or the like, or a combination thereof. In some embodiments, the dielectric layer 144 may be a bottom anti-reflective layer.

In some embodiments, a top surface of the dielectric layer 144 is lower than a top surface of the dummy gate layers 124 and higher than a bottom surface of the dummy gate layers 124. Therefore, a portion of the insulation material layer 142 disposed on the dummy structures 120 is not covered by the dielectric layer 144.

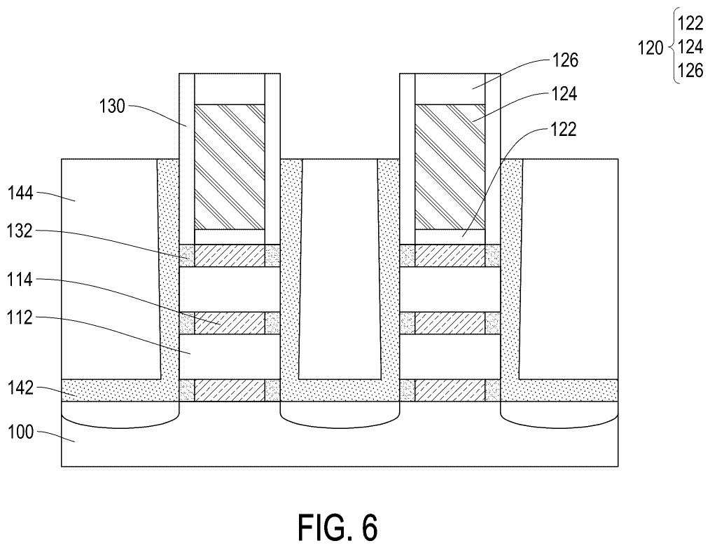

Referring to FIG. 6, the portion of the insulation material layer 142 not covered by the dielectric layer 144 is removed. For example, an etching process (such as dry etching (e.g., RIE etching), wet etching, and/or other etching methods) is performed to remove the portion of the insulation material layer 142, so that a portion of the dummy structures 120 is exposed.

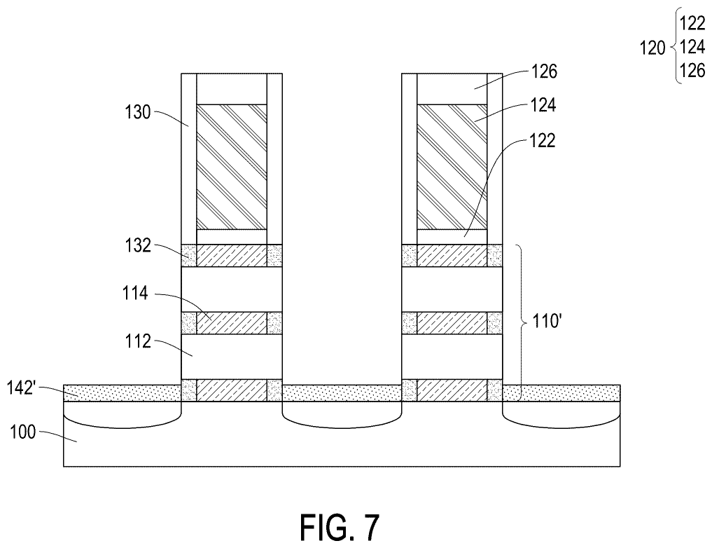

Referring to FIG. 7, the dielectric layer 144 is removed and then a portion of the insulation material layer 142 is removed. For example, one or more etching processes (such as dry etching (e.g., RIE etching), wet etching, and/or other etching methods) are performed to remove the dielectric layer 144 and the insulation material layer 142 disposed on the sidewalls of the dummy structures 120 and the stacks 110′. In some embodiments, during the etching processes, the insulation material layer 142 disposed on the leakage block layer 140 may be partially etched. After the etching processes, the insulation material layer 142 remained on the leakage block layer 140 forms the insulation layer 142′. In some embodiments, the insulation layer 142′ may function as an etch stop layer for forming frontside source/drain contacts or backside source/drain contacts in subsequent processes.

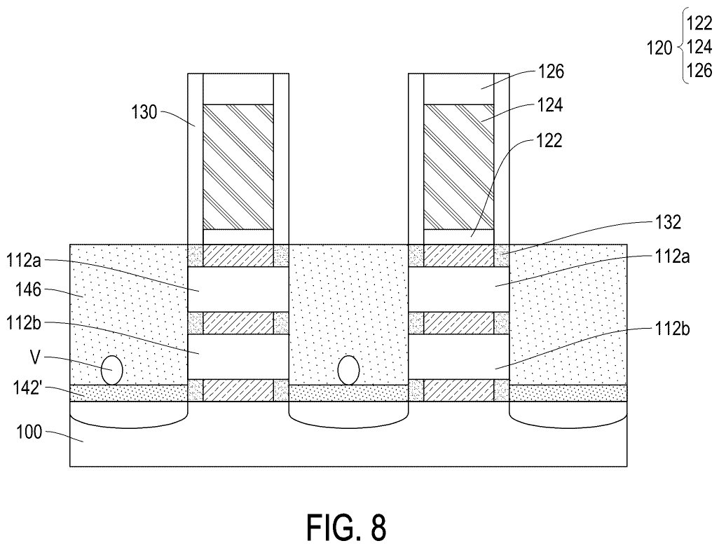

Referring to FIG. 8, source/drain structures 146 are formed over the insulation layer 142′. For example, the source/drain structures 146 is formed by an epitaxial growth process, such as VPE, UHV-CVD, MBE, and/or other suitable processes. In some embodiments, the epitaxial growth process may use gaseous and/or liquid precursors, which interact with the first semiconductor layers 112 exposed in the recesses R1. In some embodiments, the epitaxial growth of source/drain structures 146 takes place from the exposed sidewalls of the first semiconductor layers 112 and overgrow to allow the source/drain structures 146 to merge over the inner spacers 132. Therefore, the source/drain structures 146 fill up the recesses R1 between the adjacent stacks 110′. The first semiconductor layers 112 are also referred to semiconductor nanosheets 112, semiconductor channel layers 112 or semiconductor nanostructures 112 functioning as channels between the adjacent source/drain structures 146. Here, “source/drain” may refer to a source or a drain, individually or collectively dependent upon the context.

In some embodiments, during the epitaxial growth process, since the upper epitaxial structures formed from the upper first semiconductor layers 112 (e.g. first semiconductor layer 112a) of the adjacent stacks 110′ may be merged together before the lower epitaxial structures formed from the lower first semiconductor layers 112 (e.g. first semiconductor layer 112b) of the adjacent stacks 110′ are merged, few gaseous and/or liquid precursors are able to interact with the lower epitaxial structure after the upper epitaxial structures are merged, and thus voids V may be formed in the lower epitaxial structures of the source/drain structures 146. However, the embodiment is not limited thereto, in other embodiments, the voids are not formed in the source/drain structures 146.

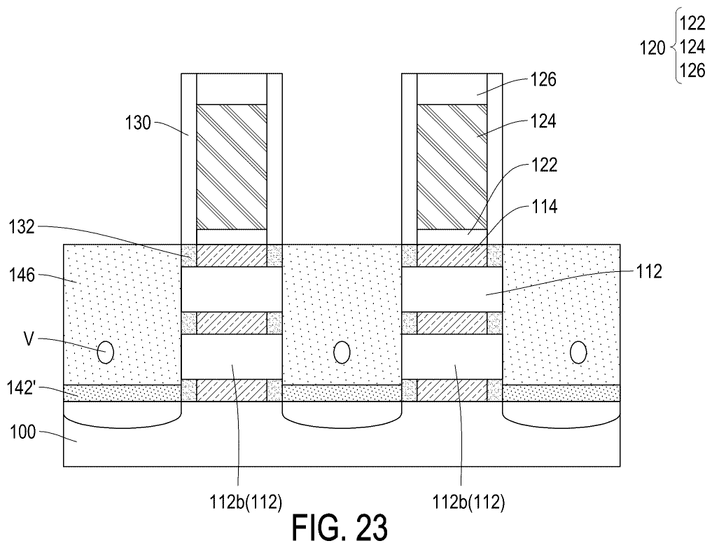

In some embodiments, the voids V may be formed in the bottom portion of the source/drain structures 146. In some embodiments, the voids V are likely to be formed between the adjacent bottommost first semiconductor layers 112 (that is, the first semiconductor layer 112b). In some embodiments, the voids V are at a level (at a position on a horizontal plane) not higher than the top surface of the bottommost first semiconductor layers 112. In some embodiments, the voids V are at a level (at a position on a horizontal plane) between the top surface of the bottommost first semiconductor layers 112 and the frontside 100a of the substrate 100. In some embodiments, the voids V are in direct contact with the insulation layer 142′, but it is not limited. In other embodiments, the voids V may not contact with the insulation layer 142′ (as shown in FIG. 23).

In some embodiments, the source/drain structures 146 are formed of epitaxial materials appropriate for either n-type or p-type transistor devices. In such embodiments, for n-type transistor devices, the materials of the source/drain structures 146 include silicon, SiC, SiCP, SiP, or the like, and for p-type devices, the materials of the source/drain structures 146 include SiGe, SiGeB, Ge, GeSn, or the like.

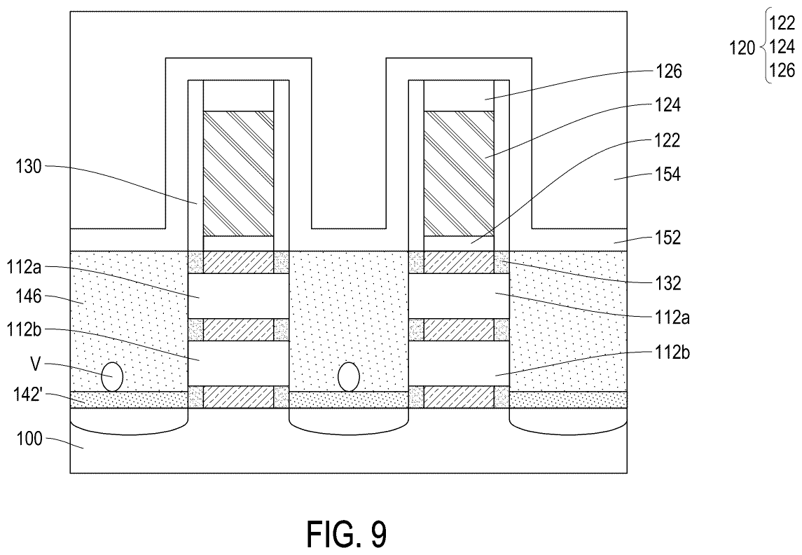

Referring to FIG. 9, a contact etch stop layer (CESL) 152 and an interlayer dielectric (ILD) layer 154 are formed on the source/drain structures 146 and the dummy structures 120. For example, the CESL 152 is first conformally deposited over the substrate 100 by CVD, ALD, PECVD process and/or other suitable deposition processes and then the ILD layer 154 is deposited on the CESL 152 by spin-on coating, flowable CVD (FCVD), CVD, or other suitable deposition technique. In some embodiments, the CESL 152 may include silicon nitride, silicon oxynitride, and/or other materials known in the art. The ILD layer 154 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

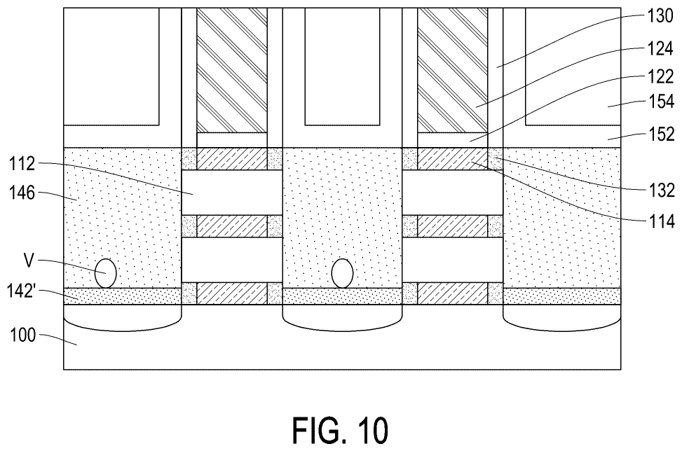

Referring to FIG. 10, a planarization process (such as chemical mechanical planarization (CMP) or the like) is performed to expose the dummy gate layers 124 of the dummy structures 120. Through the planarization process, the ILD layer 154, the CESL 152 and the sidewall spacers 130 are partially removed, and the hard mask layers 126 of the dummy structures 120 are completely removed.

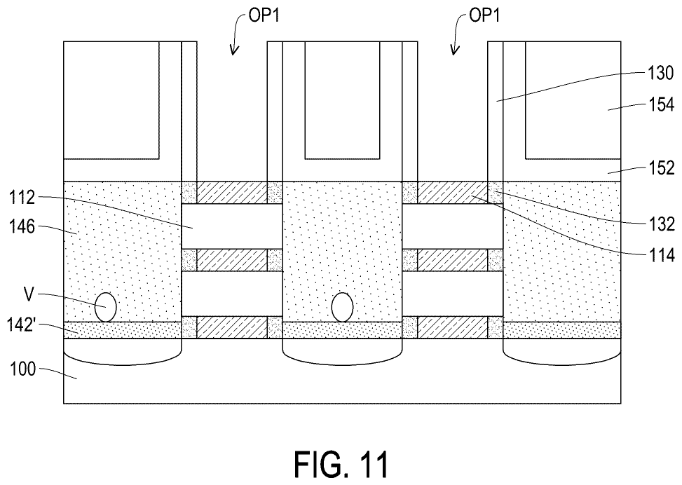

Referring to FIG. 11, the dummy gate layers 124 and the dummy dielectric layers 122 are removed to form openings OP1. For example, the dummy gate layers 124 and the dummy dielectric layer 122 are removed by one or more etching processes, such as dry etching processes, wet etching processes or a combination thereof. After the removal of the dummy gate layers 124 and the dummy dielectric layers 122, the topmost second semiconductor layers 114 of the stacks 110′ are exposed by the openings OP1, and sidewalls of the first semiconductor layers 112 and the second semiconductor layers 114 originally covered by the dummy gate layers 124 and the dummy dielectric layers 122 are exposed.

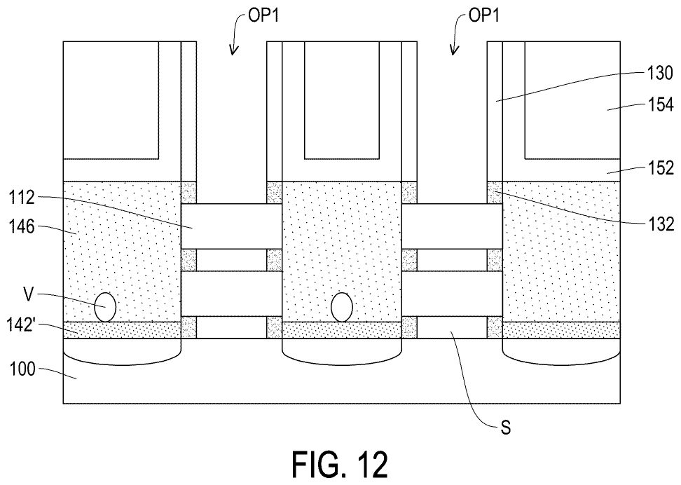

Referring to FIG. 12, the second semiconductor layers 114 are removed by performing an etching process selectively etching off the corresponding second semiconductor layers 114 with respect to the material of the inner spacers 132 and the first semiconductor layers 112. In some alternative embodiments, at least one anisotropic etching process may be performed to remove the second semiconductor layers 114. In some embodiments, the removal of the second semiconductor layers 114 of the stacks 110′ releases spaces S between the adjacent first semiconductor layers 112 and between the bottommost layer of the first semiconductor layers 112 and the substrate 100. In other words, the first semiconductor layers 112 are exposed through the spaces S.

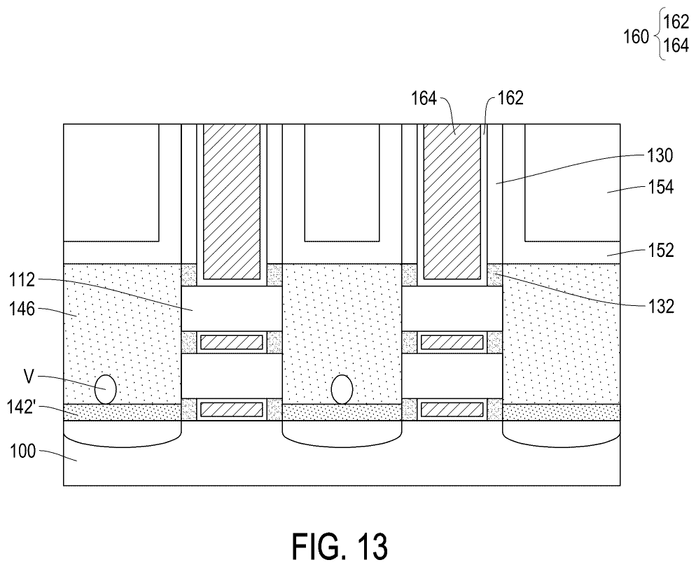

Referring to FIG. 13, gate structures 160 are formed in the openings OP1 and the spaces S. In some embodiments, each gate structure 160 includes a gate dielectric layer 162 and a gate electrode layer 164. For example, the gate structure 160 is formed by the following steps. First, the gate dielectric layer 162 is deposited directly on the exposed surfaces of the first semiconductor layers 112 to wrap around each of the first semiconductor layers 112 by ALD, CVD, and/or other suitable deposition methods. In some embodiments, the gate dielectric layer 162 may also deposited on the sidewall spacers 130. After forming the gate dielectric layer 162, the gate electrode layer 164 is formed on the gate dielectric layer 162 and fill the openings OP1 and the spaces S by PVD, ALD, CVD, or other suitable deposition processes. In some embodiments, a planarization process is performed to remove the extra materials of gate dielectric layer 162 and the gate electrode layer 164 formed on the sidewall spacers 130, the CESL 152 and the ILD layer 154. In some embodiments, the top surfaces of gate dielectric layer 162 and the gate electrode layer 164 are substantially levelled with the top surfaces of the sidewall spacers 130, the CESL 152 and the ILD layer 154.

In some embodiments, the gate dielectric layer 162 is formed of high-K dielectric materials, such as hafnium oxide, HfSiO, HfSiON, HfTaO, HfTiO, HfZrO, zirconium oxide, aluminum oxide, titanium oxide, hafnium dioxide-alumina alloy, other suitable high-k dielectric materials, and/or combinations thereof. In some embodiments, the material of the gate electrode layer 164 includes titanium (Ti), tungsten (W), vanadium (V), niobium (Nb), manganese (Mn), molybdenum (Mo), nitrides thereof or combinations thereof.

In some embodiments, through the process steps described above, a gate-all-around field effect transistor (GAA FET) structure is formed. However, it is understood that the GAA FET structure is exemplary and different transistor structures, such as fin-shaped field effect transistor (FinFET) or forksheet FET, complementary FET (CFET), may be applicable.

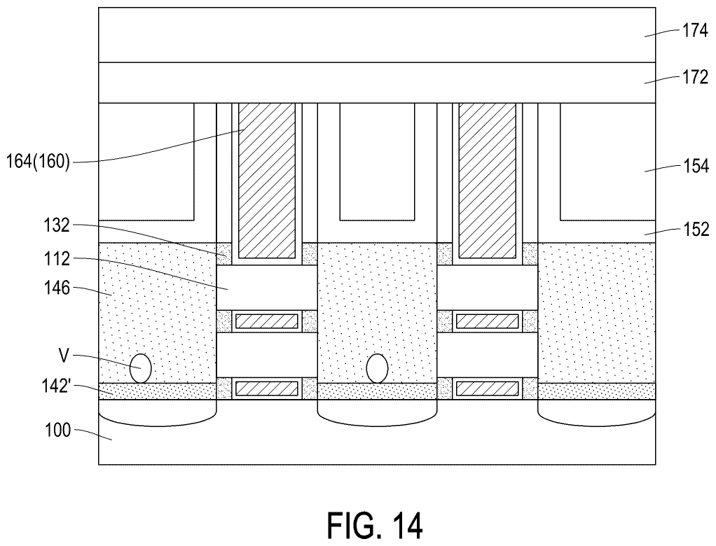

Referring to FIG. 14, a hard mask layer 172 is formed on the gate structures 160 and the ILD layer 154, and an interlayer dielectric (ILD) layer 174 is formed on the hard mask layer 172. For example, the hard mask layer 172 is first deposited over the substrate 100 to cover the gate structures 160 and the ILD layer 154 by CVD, ALD, PECVD process and/or other suitable deposition and then the ILD layer 174 is deposited on the hard mask layer 172 by spin-on coating, FCVD, CVD or other suitable deposition technique. In some embodiments, the hard mask layer 172 may include silicon nitride, silicon oxynitride, and/or other materials known in the art. The ILD layer 174 may include materials such as tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials.

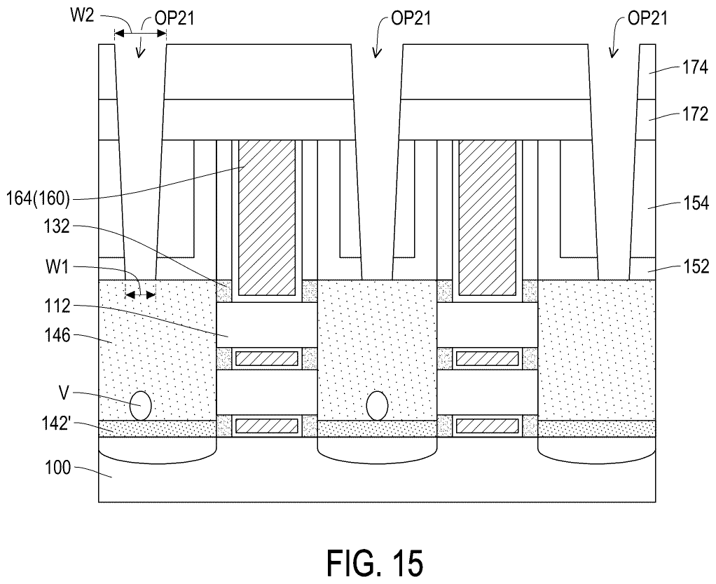

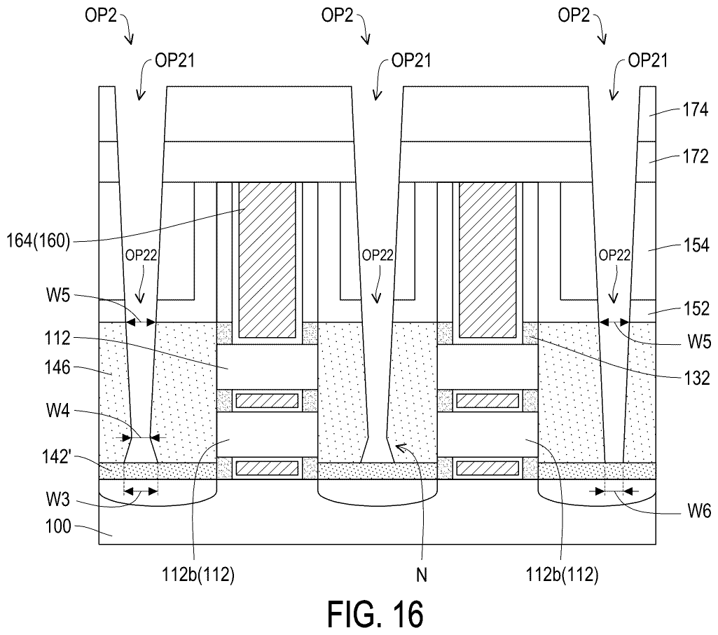

Referring to FIG. 15 and FIG. 16, frontside source/drain contact openings OP2 are formed in the ILD layer 174, the hard mask layer 172, the ILD layer 154, the CESL 152 and the source/drain structures 146 to expose the insulation layer 142′. For example, the frontside source/drain contact openings OP2 are formed by the following steps. First, as shown in FIG. 15, a patterned mask (not shown) is formed over the ILD layer 174 by a photolithography process. Then, using the patterned mask as the etch mask, the ILD layer 174, hard mask layer 172, the ILD layer 154 and the CESL 152 are patterned to transfer the pattern in the patterned mask to the ILD layer 174, hard mask layer 172, the ILD layer 154 and the CESL 152 by one or more etching processes, such as dry etching processes, wet etching processes or a combination thereof. During the pattering process of the ILD layer 174, hard mask layer 172, the ILD layer 154 and the CESL 152, first openings OP21 are formed in the ILD layer 174, hard mask layer 172, the ILD layer 154 and the CESL 152, and the first openings OP21 expose a portion of the source/drain structures 146. In some embodiments, each first opening OP21 has a taper shape. The top width W2 of the first openings OP21 is greater than the bottom width W1 of the first openings OP21. In some embodiments, the bottom width W1 of the first openings OP21 is a width measured at an end of the first openings OP21 closer to the substrate 100, and the top width W2 of the first openings OP21 is a width measured at an end of the first openings OP21 away from the substrate 100. In some embodiments, after the ILD layer 174, hard mask layer 172, the ILD layer 154 and the CESL 152 are patterned, the patterned mask is removed from over the ILD layer 174, for example, by an etching process and/or a resist stripping process.

Afterwards, as shown in FIG. 16, the source/drain structures 146 exposed by the first openings OP21 are removed by another etching process to form second openings OP22 until the insulation layer 142′ is exposed. The etching process may selectively remove source/drain structures 146 with respect to the ILD layer 174, hard mask layer 172, the ILD layer 154, the CESL 152 and the insulation layer 142′. In this way, the first openings OP21 and the second openings OP22 together forms the frontside source/drain contact openings OP2 extending through the ILD layer 174, hard mask layer 172, the ILD layer 154, the CESL 152 and the source/drain structures 146. In some embodiments, the bottom width W1 of the first opening OP21 is substantially the same to the top width W5 of the second opening OP22. The top width W5 of the second opening OP22 is a width measured at an end of the second openings OP22 away from the substrate 100.

In some embodiments, some second openings OP22 may extend through the voids V formed in the source/drain structures 146, such as the second openings OP22 shown on the left and middle in FIG. 16. In some embodiments, during the etching process of the source/drain structures 146, before the source/drain structures 146 is etched to the voids V, the width of the second openings OP22 gradually decrease as the second openings OP22 become deeper. When the source/drain structures 146 is etched to the voids V, the etchant may diffuse into the voids V formed in the source/drain structures 146, and laterally etch the source/drain structures 146 around the voids V. Besides, since the etching process selectively does not remove the insulation layer 142′, the source/drain structures 146 closer to the insulation layer 142′ is more laterally etched. Therefore, the width of the second openings OP22 gradually increase after the second openings OP22 meets the voids V. Since the second openings OP22 (or the frontside source/drain contact openings OP2) extend through the voids V formed in the source/drain structures 146, voids V in the source/drain structures 146 may be reduced, the electrical performance of the source/drain structures 146 may be improved.

In an embodiment where the second openings OP22 extend through the voids V formed in the source/drain structures 146, the second openings OP22 (or the frontside source/drain contact openings OP2) have an hourglass-like shape, which is a shape having a width of the two opposite ends of the body wider than a width of a portion of the body between the two opposite ends.

In an embodiment where the second openings OP22 extend through the voids V formed in the source/drain structures 146, the neck N of the second openings OP22 (which is the narrowest portion of the second openings OP22) may be located between the adjacent bottommost first semiconductor layers 112 (that is, the first semiconductor layer 112b). The neck N is at a level (at a position on a horizontal plane) between the top surface of the bottommost first semiconductor layer 112 (that is, the first semiconductor layer 112b) and the top surface of the insulation layer 142′. The bottom width W3 and the top width W5 of the second openings OP22 are greater than the neck width W4 of the second openings OP22. In some embodiments, the bottom width W3 of the second openings OP22 is a width measured at an end of the second openings OP22 close to the substrate 100, and the neck width W4 of the second openings OP22 is a width measured at the neck N of the second openings OP22. Therefore, the neck width W4 is the narrowest width of the second opening OP22. In some embodiments, the difference between the bottom width W3 of the second openings OP22 and the neck width W4 of the second openings OP22 (that is, W3-W4) is around 1 nm to 10 nm. In some embodiments, the top width W5 of the second openings OP22 may be greater than the bottom width W3 of the second openings OP22.

In some embodiments, the second opening OP22 may not extend through the voids V formed in the source/drain structures 146, such as the second openings OP22 shown on the right in FIG. 16. In such embodiments, the second opening OP22 (or the frontside source/drain contact opening OP2) forms a taper shape. Therefore, the bottom width W6 of the second opening OP22 is less than the top width W5 of the second opening OP22, and the bottom width W6 of the second opening OP22 is the smallest width of the second opening OP22.

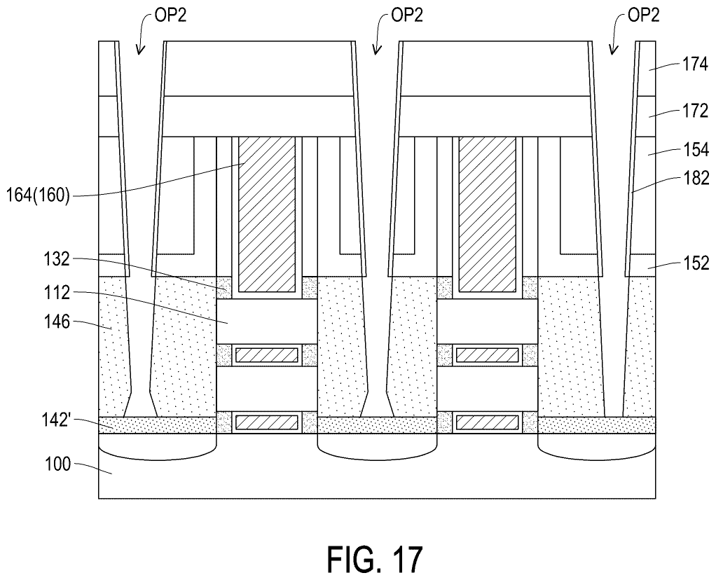

Referring to FIG. 17, protective layers 182 are formed on the sidewalls of the ILD layer 174, hard mask layer 172, ILD layer 154 and CESL 152 exposed by the frontside source/drain contact openings OP2. For example, a protective material layer (not shown) is first deposited on the ILD layer 174, sidewalls of the frontside source/drain contact openings OP2 (i.e. sidewalls of the ILD layer 174, hard mask layer 172, ILD layer 154, CESL 152 and the source/drain structures 146 exposed by the frontside source/drain contact openings OP2) and bottoms of the frontside source/drain contact openings OP2 (i.e. top surface of the insulation layer 142′ exposed by the frontside source/drain contact openings OP2) by CVD, ALD, other suitable process, or a combination thereof. In some embodiments, the protective material layer includes a dielectric material that is different from the dielectric material of the ILD layer 174. In some embodiments, dielectric material of the protective material layer includes SiO₂, SiN, SiOC, SiCN, SiOCN, SiON, AlO, or other high-k material (such as the dielectric constant k>9) or a combination thereof. Then, the protective material layer is partially removed to expose the sidewalls of the source/drain structures 146 and the top surface of the insulation layer 142′ in the frontside source/drain contact openings OP2. In some embodiments, the protective material layer may be removed by one or more etching processes, such that portions of protective material layer on the top surfaces of ILD layer 174 and the insulation layer 142′, and the lower sidewalls of the frontside source/drain contact openings OP2 (that is, sidewalls of the second openings OP22) are removed. The protective material layer remained on the upper sidewalls of the frontside source/drain contact openings OP2 (that is, sidewalls of the first openings OP21) forms the protective layers 182.

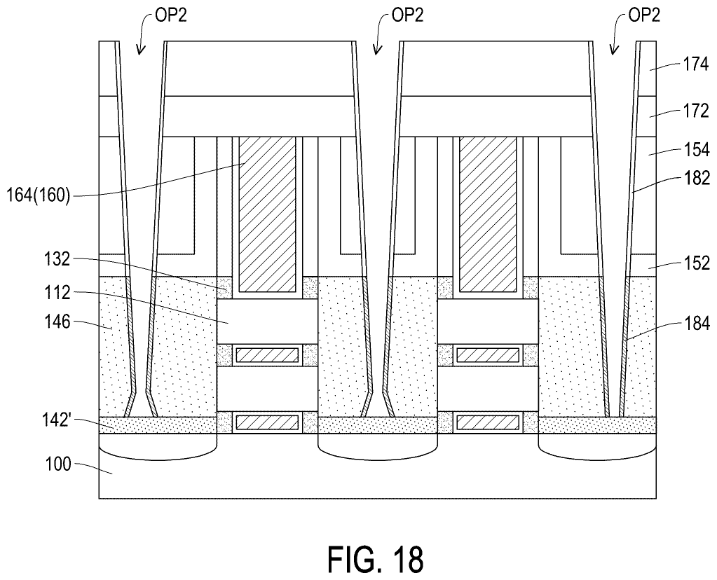

Referring to FIG. 18, silicide layers 184 are formed on sidewalls of the source/drain structures 146 exposed by the frontside source/drain contact openings OP2. For example, a silicidation process is performed to form silicide layers 184 on the exposed sidewalls of the source/drain structures 146. In some embodiments, the silicidation process may include forming a metal layer over the exposed the source/drain structures 146, and thermal treating for the metal to be reacted with silicon. In some embodiments, any un-reacted metal after the silicidation process is selectively removed by an etching process or other suitable processes. In some embodiments, the material of the silicide layers 184 includes metal silicide such as cobalt silicide (CoSi), ruthenium silicide (RuSi), nickel silicide (NiSi), titanium silicide (TiSi), or a combination thereof. The silicide layers 184 may reduce the contact resistance to the source/drain structures 146.

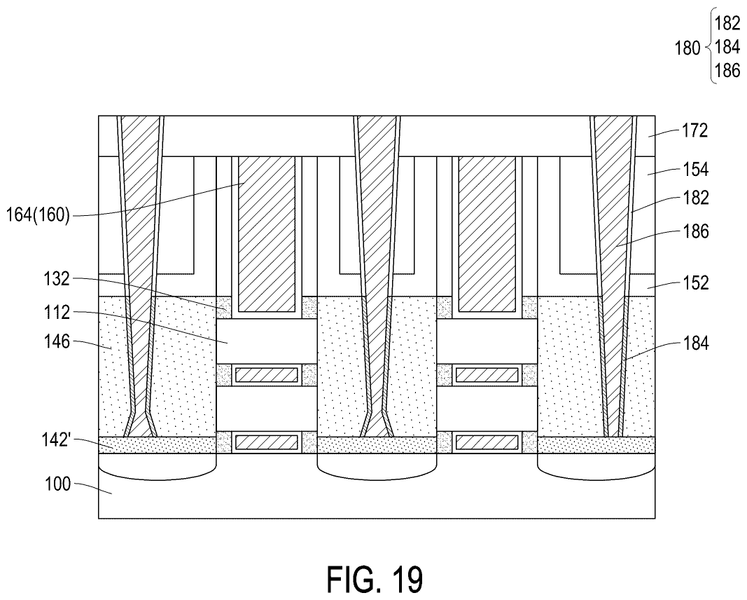

Referring to FIG. 19, metallic contacts 186 are formed in the frontside source/drain contact openings OP2. For example, a metallic material layer (not shown) is deposited over the ILD layer 174 and fill in the frontside source/drain contact openings OP2 by CVD, PVD, electrical plating, chemical plating or other suitable methods, and then a planarization process (e.g., chemical mechanical polishing (CMP)) is performed to remove portions of the metallic material(s) disposed over the hard mask layer 172. That is, the ILD layer 174 is removed during the planarization process. In some embodiments, the material of the metallic contacts 186 includes W, Co, Ru, Ir, Mo, Cu, Al, Ti, Ni, Au, Ag, Pt, Pd, alloys thereof, combinations thereof, or the like. The metallic contact 186, the silicide layer 184 and the protective layer 182 formed in each frontside source/drain contact opening OP2 are collectively referred to as frontside source/drain contact 180. Each frontside source/drain contact 180 extends through the hard mask layer 172, the ILD layer 154, the CESL 152 and the source/drain structure 146, and directly contacts with the insulation layer 142′.

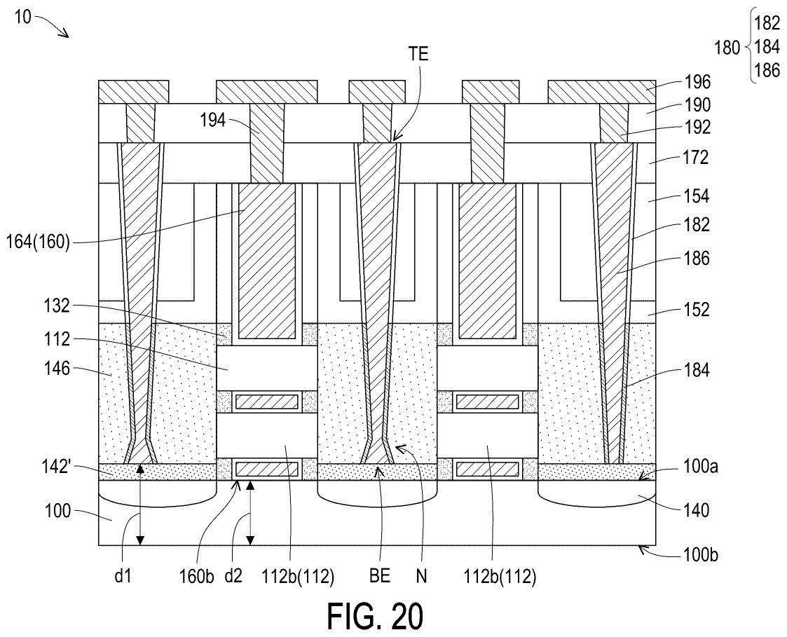

Referring to FIG. 20, frontside conductive wirings 196 are formed over the hard mask layer 172 and electrically connected to the frontside source/drain contacts 180 and the gate structures 160. For example, a dielectric layer 190 is first deposited on the hard mask layer 172 and the frontside source/drain contacts 180 by CVD, PVD or other suitable methods. Then, the dielectric layer 190 is patterned to form openings (not shown) therein that expose the frontside source/drain contacts 180. In other hands, the dielectric layer 190 and the hard mask layer 172 are patterned to form openings (not shown) therein that expose the gate structures 160. In some embodiments, the patterning of dielectric layers 190 and/or hard mask layer 172 includes using photolithography and etching processes. Afterwards, conductive materials are formed in the openings and on the dielectric layer 190 to form source/drain contact vias 192 as well as gate contact vias 194 in the openings and frontside conductive wirings 196 on the dielectric layer 190 by CVD, PVD, electrical plating, chemical plating or other suitable methods. In some embodiments, the source/drain contact vias 192 are physically and electrically connected between the frontside conductive wirings 196 and the frontside source/drain contacts 180. The gate contact vias 194 are physically and electrically connected between the frontside conductive wirings 196 and the gate structures 160. In some embodiments, the source/drain contact vias 192, the gate contact vias 194 and the frontside conductive wirings 196 may include Cu, W, Al, Ru, Co, Ni or the alloys thereof, combinations thereof, or other suitable metallic material. In some embodiments, the material of the dielectric layer 190 includes silicon oxide, PSG, BSG, BPSG, a low-k dielectric, or the like. Although FIG. 20 shows only one layer of frontside conductive wirings, but it is not limited thereto. It is understood that the number of layers of the frontside conductive wirings is not limited and may be adjusted based on practical requirements.

Based on the above, the manufacturing of the semiconductor device 10 is substantially completed.

Referring to FIG. 20, the semiconductor device 10 includes a substrate 100, semiconductor nanosheets 112, gate structures 160, source/drain structures 146, an insulation layer 142′ and frontside source/drain contacts 180. The semiconductor nanosheets 112 are stacked over the substrate 100 and spaced apart from each other. The gate structures 160 are disposed around and surrounding the semiconductor nanosheets 112. The source/drain structures 146 are disposed over the substrate 100. The semiconductor nanosheets 112 are located between the adjacent source/drain structures 146 and between the adjacent gate structures 146. The insulation layer 142′ is disposed between the source/drain structures 146 and a frontside 100a of the substrate 100. The frontside source/drain contacts 180 extend into the source/drain structures 146. A bottom end BE of the frontside source/drain contacts 180 is located between a top surface of the bottommost layer of the semiconductor nanosheets 112 (that is, the first semiconductor layer 112b) and the frontside 100a of the substrate 100.

In some embodiments, a distance d1 between the bottom end BE of the frontside source/drain contacts 180 and the frontside 100a of the substrate 100 is greater than a distance d2 between a bottommost surface 160b of the gate structure 160 and the frontside 100a of the substrate 100.

In some embodiments, each frontside source/drain contact 180 has a slant sidewall. For example, a shape of the frontside source/drain contacts 180 may include a taper shape, an hourglass-like shape or the like.

In some embodiments, a top end TE and a bottom end BE opposite to the top end TE of the frontside source/drain contact 180 are wider than a portion of the frontside source/drain contact 180 located between the top end TE and the bottom end BE.

In an embodiment where the frontside source/drain contact 180 has an hourglass-like shape, the frontside source/drain contacts 180 have the narrowest width at its neck N located between the top end TE and the bottom end BE. The neck N is lower than a top surface of the bottommost layer of the semiconductor nanosheets 112 (that is, the first semiconductor layer 112b) and higher than a top surface of the insulation layer 142′. In some embodiments, a width of the frontside source/drain contact 180 gradually decrease from the top end TE of the frontside source/drain contact 180 to the neck N of the frontside source/drain contact 180. In some embodiments, a width of the frontside source/drain contact 180 gradually increase from the neck N of the frontside source/drain contact 180 to the bottom end BE of the frontside source/drain contact 180. In some embodiments, a difference between a bottom width of the frontside source/drain contact 180 and a neck width of the frontside source/drain contact 180 is about 1 nm to 10 nm.

In an embodiment where the frontside source/drain contact 180 has a taper shape, a width of the frontside source/drain contact 180 gradually decrease from the top end TE of the frontside source/drain contact 180 to the bottom end BE of the frontside source/drain contact 180.

In some embodiments, the bottom end BE of the frontside source/drain contacts 180 are in direct contact with the insulation layer 142′. In some embodiments, a leakage block layer 140 is formed in the substrate 100 and disposed adjacent to the frontside 100a of the substrate 100. In some embodiments, the leakage block layer 140 is located directly below the insulation layer 142′.

In some embodiments, the semiconductor device 10 further includes inner spacers 132 located between the gate structures 160 and the source/drain structures 146 to electrically isolate the gate structures 160 from the source/drain structures 146.

In some embodiments, the semiconductor device 10 further includes a dielectric structure which contains the CESL 152, ILD layer 154 and the hard mask layer 172. The hard mask layer 172 is disposed on the gate structures 160. The CESL 152 and ILD layer 154 are disposed between the source/drain structures 146 and the hard mask layer 172, and between the adjacent gate structures 160. In some embodiments, the frontside source/drain contacts 180 further extends through the dielectric structure.

In some embodiments, each frontside source/drain contact 180 includes a metallic contact 186, a silicide layer 184 and a protective layer 182. The metallic contact 186 extends through a source/drain structure 146 and the dielectric structure. The silicide layer 184 wraps around the metallic contact 186, and thus the silicide layer 184 is disposed between the source/drain structure 146 and the metallic contact 186. The protective layer 182 is disposed between the dielectric structure and the metallic contact 186. In some embodiments, the silicide layer 184 surrounds a portion (e.g. lower portion) of a sidewall of the metallic contact 186, and the protective layer 182 surrounds another portion (e.g. upper portion) of the sidewall of the metallic contact 186. In some embodiments, the silicide layer 184 surrounds a portion of a sidewall of the metallic contact 186 without covering a bottom of the metallic contact 186. In some embodiments, an electrical conductivity of the metallic contacts 186 is greater than an electrical conductivity of the source/drain structures 146 and an electrical conductivity of the silicide layer 184 is greater than the electrical conductivity of the source/drain structures 146.

In some embodiments, the semiconductor device 10 further includes a dielectric layer 190 and frontside conductive wirings 196. The dielectric layer is disposed on the dielectric structure and the frontside conductive wirings 196 are disposed on the dielectric layer 190. In some embodiments, the frontside conductive wirings 196 may be electrically connected to the source/drain structures 146 by source/drain contact vias 192 formed in the dielectric layer 190. In some embodiments, the frontside conductive wirings 196 may be electrically connected to the gate structures 160 by gate contact vias 194 formed in the dielectric layer 190 and the hard mask layer 172.

Since the frontside source/drain contacts 180 extends through the source/drain structures 160 to have its bottom located below the top surface of the bottommost semiconductor nanosheets 112 and over the frontside 100a of the substrate 100, the contact area between the frontside source/drain contacts 180 and the source/drain structures 160 increases and thereby the contact resistance between the frontside source/drain contacts 180 and the source/drain structures 160 can be reduced, so that the electrical performance of the semiconductor device 10 can be improved. Besides, since the bottom of the frontside source/drain contacts 180 is at a level between the top surface of the bottommost semiconductor nanosheets 112 and the frontside 100a of the substrate 100, distances between each semiconductor nanosheets 112 and the frontside source/drain contacts 180 may be similar, and thereby the current spreading for the semiconductor nanosheets 112 (especially those semiconductor nanosheets 112 located closer to the substrate 100) may be improved.

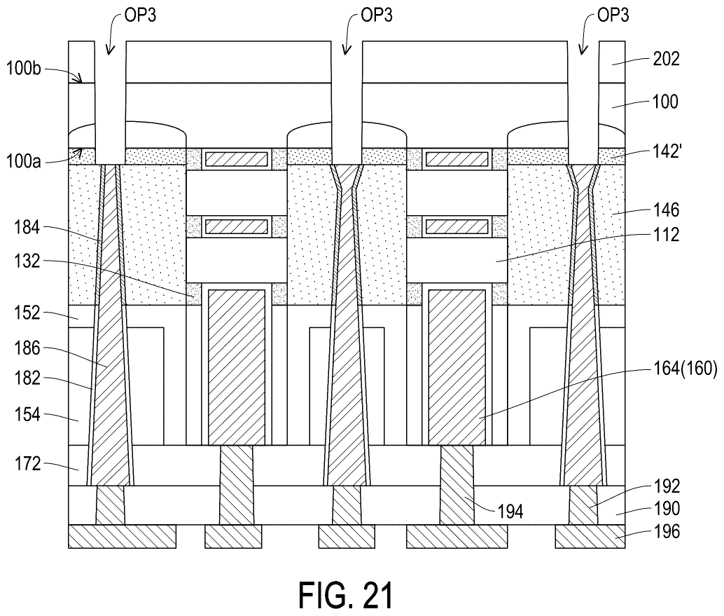

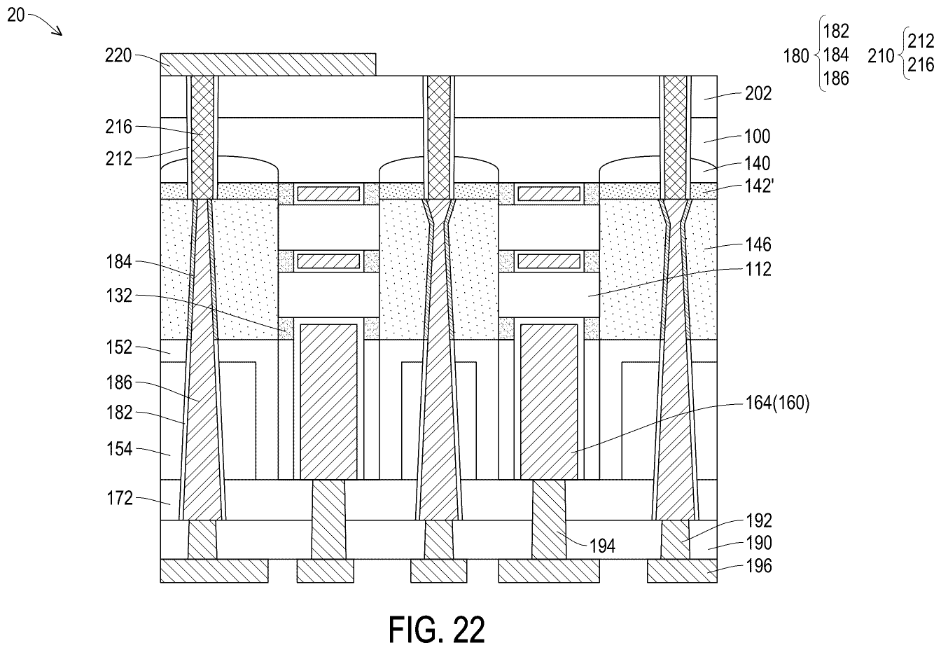

FIG. 21 through FIG. 22 are schematic cross-sectional views illustrating a portion of a semiconductor device 20 at various stages of a method for forming the semiconductor device 20 according to some embodiments of the present disclosure. It should be noted herein that, in embodiment provided in FIG. 21 through FIG. 22, element numerals and partial content of the embodiments provided in FIG. 1 through FIG. 20 are followed, the same or similar reference numerals being used to represent the same or similar elements, and description of the same technical content being omitted. For a description of an omitted part, reference may be made to the foregoing embodiment, and the descriptions thereof are omitted herein. FIG. 21 to FIG. 22 may, for example, be a continuation of the process of FIG. 1 to FIG. 20.

Referring to FIG. 21 continued from FIG. 20, the structure as shown in FIG. 20 is flipped upside down, so that the backside 100b of the substrate 100 faces up and the frontside 100a of the substrate faced down in FIG. 21. A hard mask layer 202 is formed on the backside 100b of the substrate 100 by CVD, ALD, PECVD process and/or other suitable deposition processes. Then, openings OP3 are formed in the hard mask layer 202, the substrate 100 and the insulation layer 142′ to expose the metallic contacts 186 of the frontside source/drain contacts 180. In some embodiments, the openings OP3 are formed by photolithography and etching processes (such as dry etching process, wet etching process or a combination thereof). For example, a patterned mask (not shown) is formed over hard mask layer 202 by the photolithography process. Then, using the patterned mask as the etch mask, the hard mask layer 202 is patterned to transfer the pattern in the patterned mask to the hard mask layer 202 and expose a portion of the substrate 100 by an etching process. Then, the exposed substrate 100 is removed by another etching process until the insulation layer 142′ is exposed, and after that the exposed insulation layer 142′ is removed by yet another etching process to expose the frontside source/drain contacts 180, and thereby the openings OP3 are formed. In some embodiments, before the hard mask layer 202 is formed, a thinning process may be performed to thin down the substrate 100 from the backside 100b.

Referring to FIG. 22, backside source/drain contacts 210 are formed in the openings OP3. Each backside source/drain contacts 210 includes a metallic contact 216 and a protective layer 212 laterally surrounding the metallic contact 216. For example, a protective material layer (not shown) are first deposited on the hard mask layer 202, the sidewalls of the openings OP3 (that is, sidewalls of hard mask layer 202, substrate 100 and insulation layer 142′ exposed by the openings OP3) and the bottom of the openings OP3 (that is, surfaces of the frontside source/drain contacts 180 exposed by the opening OP3) and then the protective material layer is laterally etched to form the protective layers 212 on the sidewalls of the openings OP3, similar to the forming method for the protective layer 182 described above. In some embodiments, the material of the protective layers 212 may be similar to that of the protective layer 182. After that, a metallic material layer (not shown) is deposited over the hard mask layer 202 and fill in the openings OP3 by CVD, PVD, electrical plating, chemical plating or other suitable methods, and then a planarization process (e.g., chemical mechanical polishing (CMP)) is performed to remove extra portions of the metallic material disposed over the hard mask layer 202 to form the metallic contacts 216 in the openings OP3. In some embodiments, a portion of the metallic contacts 186 of the frontside source/drain contacts 180 may be removed during the etching of the protective material layer, so that the metallic contacts 216 of the backside source/drain contacts 210 may extend into the frontside source/drain contacts 180. In some embodiments, the material of the metallic contacts 216 may be similar to that of the metallic contacts 186.

Referring to FIG. 22, backside conductive wirings 220 are formed on the hard mask layer 202 by CVD, PVD, electrical plating, chemical plating or other suitable methods. In some embodiments, the material of the backside conductive wirings 220 may be similar to that of the frontside conductive wirings 196. Although FIG. 22 shows only one layer of backside conductive wirings, but it is not limited thereto. It is understood that the number of layers of the backside conductive wirings is not limited and may be adjusted based on practical requirements.

Based on the above, the manufacturing of the semiconductor device 20 is substantially completed.

Referring to FIG. 22, the difference between the present embodiment to the embodiment of FIG. 20 is that the semiconductor device 20 further includes backside source/drain contacts 210. The backside source/drain contacts 210 extend through the substrate 100 and the insulation layer 142′ and are electrically connected to the frontside source/drain contacts 180. The backside source/drain contacts 210 are in direct contact with the frontside source/drain contacts 180, so that the contact resistance between the backside source/drain contacts 210 and the frontside source/drain contacts 180 may be reduced.

In some embodiments, the semiconductor device 20 further includes a hard mask layer 202 disposed on the backside 100b of the substrate 100. In some embodiments, the backside source/drain contacts 210 may further extend through the hard mask layer 202 and the leakage block layer 140 formed in the substrate 100.

In some embodiments, each backside source/drain contact 210 includes a metallic contact 216 and a protective layer 212. The metallic contact 216 extends through the hard mask layer 202, the substrate 100, the leakage block layer 140 and the insulation layer 142′. The protective layer 212 surrounds a sidewall of the metallic contact 216, so that the protective layer 212 may be disposed between the hard mask layer 202 the metallic contact 216, between the substrate 100 and the metallic contact 216, between the leakage block layer 140 and the metallic contact 216 and between the insulation layer 142′ and the metallic contact 216. The protective layer 212 may electrically isolate the metallic contact 216 from the substrate 100 and the leakage block layer 140. In some embodiments, the metallic contact 216 of backside source/drain contact 210 is in direct contact with the metallic contact 186 the corresponding frontside source/drain contact 180.

In an embodiment where the frontside source/drain contact 180 has an hourglass-like shape, the contact area between the frontside source/drain contact 180 and the corresponding backside source/drain contact 210 may be increased, such that the contact resistance between the frontside source/drain contact 180 and the backside source/drain contact 210 may be reduced.

In some embodiments, the semiconductor device 20 further includes backside conductive wirings 220 disposed on the hard mask layer 202. In some embodiments, the backside wirings 220 may be electrically connected to the frontside wirings 196 through the backside source/drain contacts 210 and the frontside source/drain contacts 180.

In some embodiments, the backside conductive wirings 220 may include a backside power rail to effectively use the space of the device and increase the space for frontside wirings.

FIG. 23 through FIG. 25 are schematic cross-sectional views illustrating a portion of a semiconductor device 30 at various stages of a method for forming the semiconductor device 30 according to some embodiments of the present disclosure. It should be noted herein that, in embodiment provided in FIG. 23 through FIG. 25, element numerals and partial content of the embodiments provided in FIG. 1 through FIG. 22 are followed, the same or similar reference numerals being used to represent the same or similar elements, and description of the same technical content being omitted. For a description of an omitted part, reference may be made to the foregoing embodiment, and the descriptions thereof are omitted herein. FIG. 23 may, for example, be a continuation of process of FIG. 7, and may be another embodiment relative to FIG. 8.

Referring to FIG. 23 continued from FIG. 7, the source/drain structures 146 is formed over the insulation layer 142′ by an epitaxial growth process, similar to the process described in FIG. 8 above. During epitaxial growth process, voids V are formed between the adjacent bottommost first semiconductor layers 112 (that is, the first semiconductor layer 112b) and are not in contact with the insulation layer 142′.

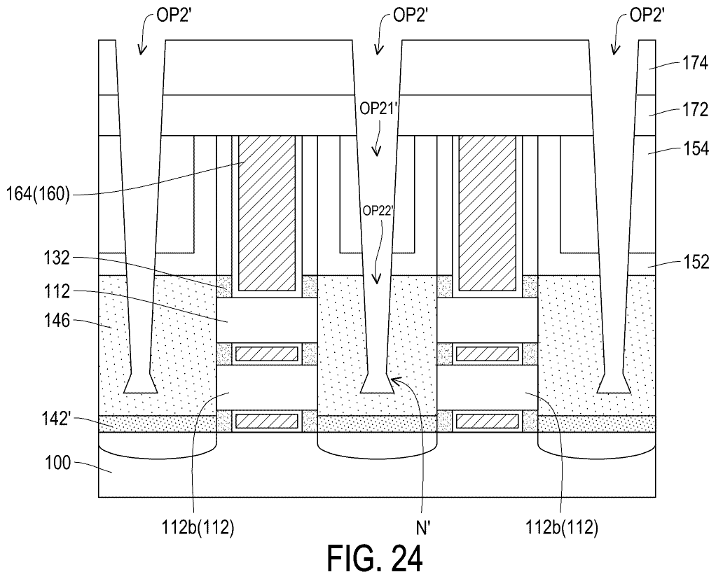

Referring to FIG. 24, the structure shown in FIG. 23 is processed by similar manners as described in FIG. 9 to FIG. 16 above to form CESL 152, ILD layer 154, gate structures 160, hard mask layer 172 and ILD layer 174. Then, frontside source/drain contact openings OP2′ are formed in the ILD layer 174, hard mask layer 172, the ILD layer 154, the CESL 152 and the source/drain structures 146. The forming of the frontside source/drain contact openings OP2′ is similar to the forming of the frontside source/drain contact openings OP2 in FIG. 16, but the etching process of the source/drain structure 146 is controlled by etch duration to make the bottom of the frontside source/drain contact openings OP2′ (or the second opening OP22′) locate below the top surface of the bottommost first semiconductor layers 112 (that is, the first semiconductor layer 112b). In this case, the frontside source/drain contact openings OP2′ (or the second opening OP22′) may not expose the insulation layer 142′, but the source/drain structure 146. That is, the bottom surface of the frontside source/drain contact openings OP2′ is composed of the source/drain structure 146.

In some embodiments, the second openings OP22′ may encounter the voids V formed in the source/drain structures 146 and thereby forms an hourglass-like shape. The neck N′ of the second openings OP22′ (which is the narrowest portion of the second openings OP22′) may be located between the adjacent bottommost first semiconductor layers 112 and below the top surface of the bottommost first semiconductor layer 112 (that is, the first semiconductor layer 112b). However, the embodiment is not limited thereto. In other embodiments, the second openings OP22′ may not encounter the voids V formed in the source/drain structures 146 and thereby forms a taper shape.

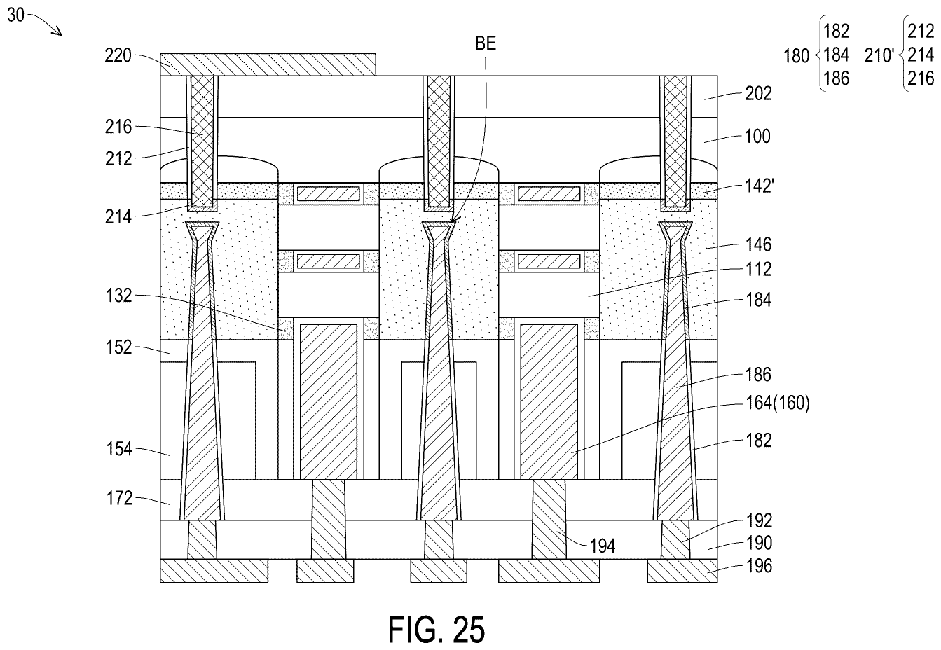

Referring to FIG. 25, the structure shown in FIG. 24 is processed by similar manners as described in FIG. 17 to FIG. 22 above to form frontside source/drain contacts 180, dielectric layer 190, source/drain contact vias 192, gate contact vias 194, frontside conductive wirings 196, backside source/drain contacts 210′ and backside wirings 220. In this embodiment, each backside source/drain contact 210′ includes not only a protective layer 212 and a metallic contact 216, but also a silicide layer 214 to reduce the contact resistance with the source/drain structure 146. In some embodiment, the silicide layer 214 is formed on the source/drain structure 146 exposed by the opening formed in the hard mask layer 202, the substrate 100 and the insulation layer 142′ (not shown) before the metallic contact 216 is formed. The silicide layer 214 may formed by a similar manner as the forming of the silicide layer 184 described above.

Based on the above, the manufacturing of the semiconductor device 30 is substantially completed.

Referring to FIG. 25, the difference between the present embodiment to the embodiment of FIG. 22 is that in the semiconductor device 30, the backside source/drain contacts 210′ are not in direct contact with the frontside source/drain contacts 180, and the backside source/drain contacts 210′ are in direct contact with the source/drain structures 146. A portion of the source/drain structures 146 is sandwiched between the backside source/drain contacts 210′ and the bottom end BE of the frontside source/drain contacts 180 and/or between the insulation layer 142′ and the bottom end BE of the frontside source/drain contacts 180. A bottom end BE of the frontside source/drain contacts 180 is at a level (at a position on a horizontal plane) between a top surface of the bottommost layer of the semiconductor nanosheets 112 and a top surface of the insulation layer 142′. Here, the terms “top” and “bottom” hereinafter are relative to the substrate 100. For example, the top surface or the topmost layer is a surface or layer located furthest from the substrate 100, whereas the bottom surface or the bottommost layer is a surface or layer located closest to the substrate 100.

In some embodiments, each backside source/drain contacts 210′ includes a metallic contact 216, a protective layer 212 and a silicide layer 214. The silicide layer 214 is located between the metallic contact 216 and a source/drain structure 146. In some embodiments, the silicide layer 214 is located at an end of the metallic contact 216 close to the source/drain structure 146.

In some embodiments, a silicide layer 184 of a frontside source/drain contact 180 surrounds a portion of a sidewall of the metallic contact 186 of the frontside source/drain contact 180 and also extends to a bottom of the metallic contact 186. Therefore, a portion of the source/drain structure 146 is located between the silicide layer 184 of the frontside source/drain contact 180 and the silicide layer 214 of the backside source/drain contact 210′.

Although FIG. 25 shows that the frontside source/drain contacts 180 have an hourglass-like shape, but it is not limited thereto. In other embodiments, the frontside source/drain contacts 180 have a taper shape as described above. Besides, FIG. 25 schematically shows the backside source/drain contacts 210′ and backside conductive wirings 220, but it is understood the semiconductor device 30 may not include the backside source/drain contacts 210′ and backside conductive wirings 220.

In accordance with some embodiments, a semiconductor device is described. The semiconductor device includes a substrate, semiconductor channel layers, a gate structure, source/drain structures, an interlayer dielectric layer, an insulation layer and a frontside source/drain contact. The semiconductor channel layers are stacked over the substrate and spaced apart from each other. The gate structure wraps the semiconductor channel layers. The source/drain structures are disposed over the substrate. The semiconductor channel layers are located between the adjacent source/drain structures and coupling to the source/drain structures. The interlayer dielectric layer is disposed over the source/drain structures. The insulation layer is disposed between the source/drain structures and a frontside of the substrate. The frontside source/drain contact extends into the interlayer dielectric layer and one of the source/drain structures. A bottom end of the frontside source/drain contact is located between a top surface of a bottommost semiconductor channel layer of the semiconductor channel layers and the frontside of the substrate and a distance between the bottom end of the frontside source/drain contact and the frontside of the substrate is greater than a distance between a bottom surface of the gate structure and the frontside of the substrate.

In accordance with another embodiment, a semiconductor device is described. The semiconductor device includes a substrate, semiconductor nanostructures, a gate structure, source/drain structures, a frontside source/drain contact and a backside source/drain contact. The semiconductor nanostructures are stacked over the substrate and spaced apart from each other. The gate structure wraps the semiconductor nanostructures. The source/drain structures are disposed over the substrate. The semiconductor nanostructures and the gate structure are located between the adjacent source/drain structures. The frontside source/drain contact extends through one of the source/drain structures. The backside source/drain contact extends through the substrate and is in direct contact with the frontside source/drain contact.

In accordance with yet another embodiment of the disclosure, a method for forming a semiconductor device is described. The method at least includes the following steps. Semiconductor channel layers are formed over a substrate. An insulation layer is formed on a frontside of the substrate. Source/drain structures are formed on the insulation layer. The semiconductor channel layers are located between the adjacent source/drain structures and coupling to the source/drain structures. An interlayer dielectric layer is formed over the source/drain structures. A gate structure is formed to wrap the semiconductor channel layers. A frontside source/drain contact is formed extending into the interlayer dielectric layer and one of the source/drain structures. A bottom of the frontside source/drain contact is located between a top surface of a bottommost semiconductor channel layer of the semiconductor channel layers and the frontside of the substrate and a distance between the bottom end of the frontside source/drain contact and the frontside of the substrate is greater than a distance between a bottom surface of the gate structure and the frontside of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
semiconductor channel layers stacked over the substrate and spaced apart from each other;
a gate structure wrapping the semiconductor channel layers;
source/drain structures disposed over the substrate, wherein the semiconductor channel layers are located between the adjacent source/drain structures and coupling to the source/drain structures;
an interlayer dielectric layer disposed over the source/drain structures;
an insulation layer disposed between the source/drain structures and a frontside of the substrate; and
a frontside source/drain contact extending into the interlayer dielectric layer and one of the source/drain structures, wherein a bottom end of the frontside source/drain contact is located between a top surface of a bottommost semiconductor channel layer of the semiconductor channel layers and the frontside of the substrate, and a distance between the bottom end of the frontside source/drain contact and the frontside of the substrate is greater than a distance between a bottommost surface of the gate structure and the frontside of the substrate.

2. The semiconductor device of claim 1, wherein the bottom end and a top end opposite to the bottom end of the frontside source/drain contact are larger than a portion of the frontside source/drain contact located between the top and bottom ends.

3. The semiconductor device of claim 2, wherein the frontside source/drain contact has a neck located between the top and bottom ends, and the neck is lower than the top surface of the bottommost semiconductor channel layer and higher than a top surface of the insulation layer.

4. The semiconductor device of claim 1, wherein the bottom end of the frontside source/drain contact is in direct contact with the insulation layer.

5. The semiconductor device of claim 1, wherein a portion of the source/drain structures is sandwiched between the bottom end of the frontside source/drain contact and the insulation layer.

6. The semiconductor device of claim 1, wherein the frontside source/drain contact comprises a metallic contact and a silicide layer wrapping around the metallic contact, wherein an electrical conductivity of the metallic contact is greater than an electrical conductivity of the source/drain structures and an electrical conductivity of the silicide layer is greater than the electrical conductivity of the source/drain structures.

7. The semiconductor device of claim 6, wherein the silicide layer surrounds a portion of a sidewall of the metallic contact without covering a bottom of the metallic contact.

8. The semiconductor device of claim 1, further comprising a backside source/drain contact extending through the substrate and the insulation layer and electrically connected to the frontside source/drain contact.

9. A semiconductor device, comprising:
a substrate;
semiconductor nanostructures stacked over the substrate and spaced apart from each other;
a gate structure wrapping the semiconductor nanostructures;
source/drain structures disposed over the substrate, wherein the semiconductor nanostructures and the gate structure are located between the adjacent source/drain structures;
a frontside source/drain contact extending through one of the source/drain structures; and
a backside source/drain contact extending through the substrate and in direct contact with the frontside source/drain contact.

10. The semiconductor device of claim 9, wherein the frontside source/drain contact has a slant sidewall, and a distance between a bottom end of the frontside source/drain contact and a frontside of the substrate is greater than a distance between a bottommost surface of the gate structure and the frontside of the substrate.

11. The semiconductor device of claim 9, further comprising a lower insulation layer disposed between the source/drain structures and the substrate.

12. The semiconductor device of claim 11, wherein the backside source/drain contact comprises:
a first metallic contact extending through the substrate and the insulation layer; and
a first protective layer disposed between the substrate and the first metallic contact.

13. The semiconductor device of claim 12, wherein the frontside source/drain contact comprises:
a second metallic contact extending through the one of the source/drain structures;
a silicide layer disposed on a lower portion of a sidewall of the second metallic contact; and
a second protective layer disposed on an upper portion of the sidewall of the second metallic contact.

14. The semiconductor device of claim 13, wherein the second metallic contact is in direct contact with the first metallic contact.

15. A method of forming a semiconductor device, comprising:
forming semiconductor channel layers over a substrate;
forming an insulation layer on a frontside of the substrate;
forming source/drain structures on the insulation layer, wherein the semiconductor channel layers are located between the adjacent source/drain structures and coupling to the source/drain structures;
forming an interlayer dielectric layer over the source/drain structures;
forming a gate structure to wrap the semiconductor channel layers; and
forming a frontside source/drain contact extending into the interlayer dielectric layer and one of the source/drain structures, wherein a bottom of the frontside source/drain contact is located between a top surface of a bottommost semiconductor channel layer of the semiconductor channel layers and the frontside of the substrate and a distance between the bottom end of the frontside source/drain contact and the frontside of the substrate is greater than a distance between a bottommost surface of the gate structure and the frontside of the substrate.

16. The method of claim 15, wherein forming the frontside source/drain contact comprises:
forming a frontside source/drain contact opening in the one of the source/drain structures;
forming a silicide layer on the one of the source/drain structures exposed by the frontside source/drain contact opening; and
filling a metallic material in the frontside source/drain contact opening to form a metallic contact.

17. The method of claim 16, wherein the source/drain structures is formed by an epitaxial growth process, and voids are formed in the source/drain structures during the epitaxial growth process.

18. The method of claim 17, wherein the frontside source/drain contact opening extends through the voids formed in the source/drain structures, and thereby forms an hourglass-like shape.

19. The method of claim 16, wherein the frontside source/drain contact opening exposes the insulation layer.

20. The method of claim 15, further comprising:
forming a backside source/drain contact extending through the substrate and the insulation layer.
